(19) United States
(12) Patent Application Publication
(10) Pub. No.: US 2005/0029011 A1
(43) Pub. Date: Feb. 10, 2005

(54) Circuit board

(75) Inventors: Toshifumi Morita, Ozu-shi (JP); Shigetoshi Segawa, Nihama-shi (JP)

Correspondence Address: MERCHANT & GOULD PC, P.O. BOX 2903, MINNEAPOLIS, MN, 55402-0903, US

(73) Assignee: MATSUSHITA ELECTRIC INDUSTRIAL CO., LTD., Kadoma-shi (JP)

(21) Appl. No.: 10/911,148

(22) Filed: Aug. 3, 2004

(30) Foreign Application Priority Data
Aug. 7, 2003 (JP) 2003-288744

(51) Int. Cl. H05K 1/11

(52) U.S. Cl. 174/255; 174/262; 174/257

(57) ABSTRACT

A circuit board including a plurality of substrates fixed on a main substrate with solder, wherein the plurality of substrates include a substrate having a smaller thermal expansion coefficient than the main substrate, and wherein the plurality of substrates are made by bonding together a ceramic substrate and a substrate having a higher strength than the ceramic substrate, with the higher-strength substrate bonded to the main substrate side of the ceramic substrate. Since a substrate having a higher strength than a ceramic substrate is bonded to the main substrate side of the ceramic substrate, it is possible to reduce the thermal stress applied to the ceramic substrate side of the circuit board so as to prevent cracking in the ceramic substrate, thus improving the reliability of the circuit board against a thermal stress.

### BACKGROUND OF THE INVENTION

1. Field of the Invention

The present invention relates to circuit boards on which electronic components and the like are mounted.

2. Description of the Related Art

A conventional circuit board is described below. In a conventional circuit board, as shown in FIG. 4, a semiconductor integrated circuit 2 is mounted on a circuit board 1 made of a ceramic (hereinafter, referred to as “ceramic substrate”) 1 with an adhesive layer 21 interposed between the semiconductor integrated circuit 2 and the ceramic substrate 1. In addition, terminal pads 3 are disposed on the undersurface of the ceramic substrate 1 and connected to the semiconductor integrated circuit 2 with wiring patterns, through holes and the like.

On a main substrate 4 made of resin, connection pads 5 are disposed in positions corresponding to the terminal pads 3. Then, the connection pads 5 and the terminal pads 3 are connected with solder 6 electrically and mechanically.

As an example of the documents on the above-described conventional art pertaining to the present invention, JP H10-107398A is known.

However, when the above-described conventional ceramic substrate 1 is placed on the main substrate 4 made of resin and the two substrates are fixed with the solder 6 electrically and mechanically, the following problems arise due to the difference in thermal expansion coefficient between the materials of the two substrates.

That is, the thermal expansion coefficient of the main substrate 4 is approximately three times that of the ceramic substrate 1, which has been fired at a low temperature. When the substrates 1 and 4, which differ in thermal expansion coefficient, are fixed to each other with the solder 6 and exposed to a thermal stress, the substrates 1 and 4 exert stress on each other, as shown in FIG. 5. Due to this stress, a force is exerted that pulls the ceramic substrate 1 outward, as indicated by the arrow 7. Accordingly, there is a possibility that cracking occurs in the ceramic substrate 1.

### SUMMARY OF THE INVENTION

Therefore, in order to solve the above-described problems of the conventional art, it is an object of the present invention to provide a circuit board with improved reliability against a thermal stress by reducing the thermal stress applied to the ceramic substrate side of the circuit board so as to prevent cracking in the ceramic substrate.

A circuit board according to the present invention includes a plurality of substrates fixed on a main substrate with solder, wherein the plurality of substrates include a substrate having a smaller thermal expansion coefficient than the main substrate, and wherein the plurality of substrates are made by bonding together a ceramic substrate and a substrate having a higher strength than the ceramic substrate, with the higher-strength substrate bonded to the main substrate side of the ceramic substrate.

### BRIEF DESCRIPTION OF THE DRAWINGS

FIG. 1 is a cross-sectional view of a circuit board mounted on a main substrate according to one embodiment of the present invention.

FIG. 2 is a cross-sectional view of solder connecting the main substrate and the circuit board.

FIG. 3 is a cross-sectional view of the main substrate and the circuit board connected with the solder.

FIG. 4 is a cross-sectional view of a conventional circuit board mounted on a main substrate.

FIG. 5 is a cross-sectional view for illustrating a case where a thermal stress is applied to the conventional circuit board.

FIG. 6 is a graph showing the change in connection resistance in the case of providing no alumina substrate and using solder balls.

FIG. 7 is a graph showing the change in connection resistance in the case of providing an alumina substrate with a thickness of 0.50 mm and using solder balls.

FIG. 8 is a graph showing the change in connection resistance in the case of providing no alumina substrate and using resin balls.

FIG. 9 is a graph showing the change in connection resistance in the case of providing an alumina substrate with a thickness of 0.19 mm and using resin balls.

FIG. 10 is a graph showing the change in connection resistance in the case of providing an alumina substrate with a thickness of 0.28 mm and using resin balls.

FIG. 11 is a graph showing the change in connection resistance in the case of providing an alumina substrate with a thickness of 0.50 mm and using resin balls.

FIG. 12 is a graph showing heat cycle conditions.

### DESCRIPTION OF THE PREFERRED EMBODIMENTS

The present invention provides a circuit board that is fixed on a main substrate having a large thermal expansion coefficient with solder and that has a smaller thermal expansion coefficient than the main substrate, and the circuit board is made by bonding together a ceramic substrate and a substrate having a higher strength than the ceramic substrate, with the higher-strength substrate bonded to the main substrate side of the ceramic substrate. Accordingly, it is possible to prevent cracking in the ceramic substrate even when a thermal stress is applied to the ceramic substrate, thus improving the reliability of the circuit board against a thermal stress.

It is preferable that the higher-strength substrate is an alumina substrate. This leads to an increase in the strength of the ceramic substrate. The thickness of the alumina substrate is preferably in the range of at least 0.19 mm and at most 0.5 mm.

It is preferable that the alumina substrate is provided with at least one through hole in thickness direction, and a conductive paste is filled into the through hole so as to achieve electrical conduction. This enables a conductor that is wired to the alumina substrate to be brought into an electrical connection with the ceramic substrate.

It is preferable that the through hole has a diameter in the range of at least 0.1 mm and at most 0.3 mm. This can enhance the ability of the conductive paste to be filled into the through hole provided in the alumina substrate.

For a similar reason, it is also preferable that the following relation ship is satisfied:
0.9B≦A≦2.5B
where A is a diameter of the through hole and B is a thickness of the alumina substrate.

It is preferable that a wiring pattern is provided on the alumina substrate, the wiring pattern is connected to the through hole and a connection is made through the wiring pattern to another circuit disposed on the ceramic substrate. Since the circuit board thus has the wiring pattern, wiring can be provided to a connection pad with this wiring pattern, increasing the flexibility of the layout of the connection pad.

It is preferable that a terminal pad for connection disposed on the alumina substrate and a connection pad for connection disposed on the main substrate are connected with a resin ball formed by a spherically formed resin, at least one layer of a conductive metal covering an outer surface of the resin and a solder layer covering an outer surface of the metal. This allows the resin formed in the solder to absorb a stress, thus reducing the stress applied to the alumina substrate.

It is preferable that the metal layer of the resin ball is copper. This is for the purpose of maintaining favorable electrical conduction.

It is preferable that a terminal pad for connection disposed on the alumina substrate and a connection pad for connection disposed on the main substrate are connected with a solder ball including metal. This makes it possible to connect the alumina substrate and the main substrate with a conventionally used solder ball.

It is preferable that the ceramic substrate and the higher-strength substrate are integrated in one piece by sintering. This allows the two substrates to be bonded strongly.

With the present invention, since a substrate having a higher strength than a ceramic substrate is bonded to the main substrate side of the ceramic substrate, the thermal stress applied to the ceramic substrate side of the circuit board can be reduced. Accordingly, it is possible to prevent cracking in the ceramic substrate, thus improving the reliability of the circuit board against a thermal stress.

Embodiment 1

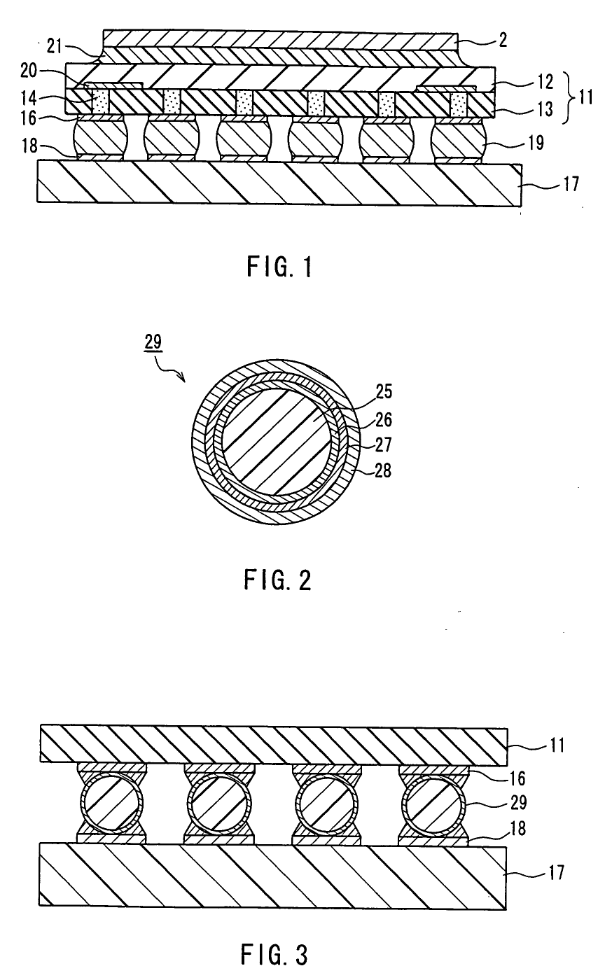

One embodiment of the present invention is described below with reference to the accompanying drawings. FIG. 1 is a cross-sectional view of a circuit board 11 mounted on a main substrate 17 made up of a so-called glass epoxy substrate (having a thickness of 2.5 mm), which is obtained by impregnating glass fiber woven fabric with an epoxy resin, followed by curing. This circuit board 11 is constituted by a low-temperature-fired ceramic substrate 12 having a thickness of 0.65 mm and a transverse rupture strength of 250 MPa and an alumina substrate 13 having a thickness of 0.28 mm and being bonded to the underside of the low-temperature-fired ceramic substrate 12. The low-temperature-fired ceramic substrate 12 and the alumina substrate 13 are fixed by bonding the low-temperature-fired ceramic substrate 12 to the alumina substrate 13 by thermocompression bonding (with a temperature of about 90° C. and a pressure of about 20 MPa), and thereafter, sintering them into one piece at about 900° C.

The alumina substrate 13 has a transverse rupture strength of 350 MPa, which is about 40% greater than that of the low-temperature-fired ceramic substrate 12 (250 MPa). Thus, the transverse rupture strength of the low-temperature-fired ceramic substrate 12 is made substantially larger.

It should be noted that the low-temperature-fired ceramic substrate 12 is obtained by firing, at about 900° C., a green sheet that has been formed by adding an organic binder to a powder containing about 50 mass percent of alumina and about 50 mass percent of glass.

The alumina substrate 13 may contain 96 mass percent of alumina (the remainder are unavoidable natural elements), and is provided with through holes 14 having a diameter of 0.2 mm downwardly from its upper surface. A conductive paste 15 containing silver as the main component is filled into the through holes 14. Terminal pads 16 connected to the through holes 14 are disposed on the undersurface of the alumina substrate 13.

Connection pads 18 are disposed on the upper surface of the main substrate 17 in positions corresponding to the terminal pads 16, and the connection pads 18 and the terminal pads 16 are fixed to each other with solder 19 interposed therebetween. Thus, the main substrate 17 and the circuit board 11 are fixed with the solder 19. Here, since the low-temperature-fired ceramic substrate 12 and the alumina substrate 13 having a large transverse rupture strength of the circuit board 11 are bonded and integrated into one piece by sintering, no cracking will occur in the low-temperature-fired ceramic substrate 12 even when the thermal expansion coefficient of the main substrate 17 is larger than that of the low-temperature-fired ceramic substrate 12 and thermal stress is applied to the low-temperature-fired ceramic substrate 12.

A semiconductor integrated circuit 2 is fastened to the upper surface of the ceramic substrate 12 with an adhesive layer 21 made of an epoxy resin disposed between the semiconductor integrated circuit 2 and the ceramic substrate 12, and connected to the ceramic substrate 12 with wiring. The wiring is connected to wiring patterns 20 provided on the upper surface of the alumina substrate 13. These wiring patterns 20 are connected to the through holes 14, and guided to the main substrate 17 through the conductive paste 15 filled into the through holes 14. Eventually, a signal from the semiconductor integrated circuit 2 is passed, via the wiring of the ceramic substrate 12, the wiring patterns 20, the conductive paste 15, the terminal pads 16, the solder 19 and the connection pads 18 in this order, and guided to the main substrate 17.

As described above, since the wiring patterns 20 are provided on the alumina substrate 13 and a connection is made to the through holes 14 with the wiring patterns 20, the degree of design flexibility (e.g., forming the through holes 14 at a fixed interval) can be increased.

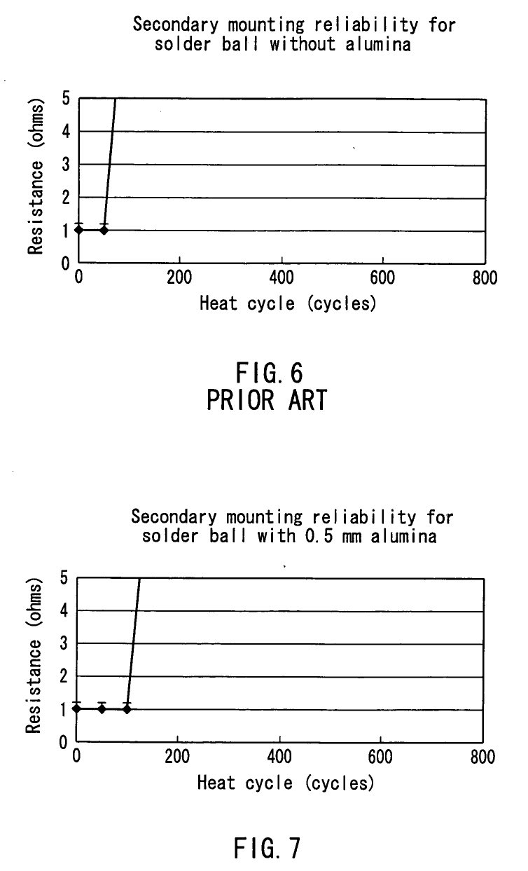

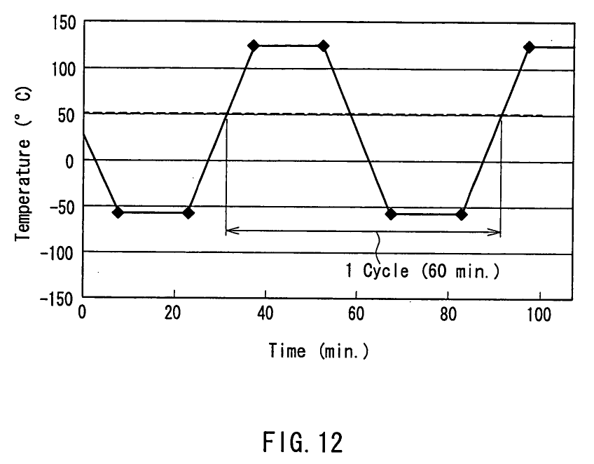

Table 1 shows the thickness of the alumina substrate 13, the through hole filling quality at the time of filling the conductive paste into the through holes 14 and the test results of heat cycle, in the case of using a eutectic solder ball made of 63Sn/37Pb as the solder 19. Each sample (except for the one in which no alumina substrate was provided) was formed by bonding an alumina substrate 13 containing 96 mass percent of alumina (the remainder are unavoidable natural elements) to a ceramic substrate 12 having a thickness of 0.65 mm. In each sample, the size of the semiconductor integrated circuit 2 disposed on the ceramic substrate 12 was 25.4×25.4 mm, the number of pins was 144 and the diameter of the through holes 14 provided in the alumina substrate 13 was 0.2 mm. FIGS. 6 and 7 show the number of heat cycles and the change in connection resistance between the ceramic substrate 12 and the main substrate 17. FIG. 12 shows the heat cycle conditions in the present example. The temperature range of the heat cycle was from −55° C. to +125° C. Each test was started at −55° C., and the temperature was increased to 125° C. over about 15 minutes and maintained at 125° C. for 15 minutes. Thereafter, the temperature was decreased to −55° C. over about 15 minutes and maintained at −55° C. for 15 minutes. The above-described series of temperature changes was considered as one cycle. As for the through hole filling quality, both surfaces of the alumina substrate 13 were observed with a microscope with ×20 magnification and the following were evaluated by visual inspection:
(1) whether the conductive paste was filled to the opposite surface of the through holes, viewed from the printed side;
(2) whether no remarkable extrusion (approximately 0.1 mm) of the conductive paste was present on the printed surface and the opposite surface; and

(3) whether no perforation was present in the through holes into which the conductive paste was filled. In the evaluation results, “A” means excellent, “B” means acceptable and “C” means unacceptable.

TABLE 1

| | | number of cycles | |
|---|---|---|---|
| | | during which | |
| thickness of | through hole | reliability was | |
| alumina (mm) | filling quality | ensured | remarks |
| nil | — | 50 | |
| 0.15 | B | — | — |
| 0.19 | A | 100 | — |
| 0.28 | A | 100 | — |
| 0.5 | A | 100 | |
| 0.635 | B | — | — |
| 1 | C | — | — |

As clearly seen from Table 1, the through hole filling quality is related to the thickness of the alumina substrate. In the present example, the conductive paste was not filled into the through holes sufficiently when the thickness of the alumina substrate was 0.635 mm. The reason was that since the depth of the through holes was too much larger than their diameter, the conductive paste was not filled sufficiently and thus was unable to reach from the printed side to the opposite side. When the thickness of the alumina substrate was in the range from 0.19 mm to 0.5 mm, the conductive paste could be filled into the through holes completely. When the thickness of the alumina substrate was 0.15 mm, the conductive paste could not be held in the through holes since the depth of the through holes was smaller than their diameter, resulting in perforations. In terms of the through hole filling quality, an appropriate thickness of the alumina substrate 13 is 0.19 mm to 0.5 mm, when the diameter of the through holes 14 provided in the alumina substrate 13 is 0.2 mm. The number of cycles during which the reliability was ensured was 50 cycles in the case of the sample in which no alumina substrate was bonded (FIG. 6), whereas the number increased to 100 cycles in the case of the sample of the present example in which the alumina substrate with an appropriate thickness was bonded (FIG. 7). That is, the connection made with the eutectic solder balls of the present example can attain the reliability twice that of the conventional connection.

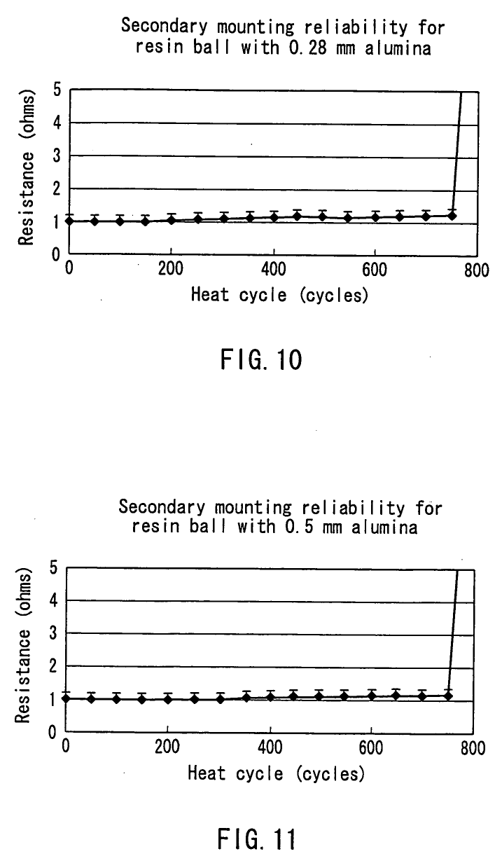

Table 2 shows the thickness of the alumina substrate 13, the through hole filling quality at the time of filling the conductive paste into the through holes 14 and the test results of the heat cycle, in the case of using a resin ball as the solder 19. Each sample (except for the one in which no alumina substrate was provided) was formed by bonding an alumina substrate 13 containing 96 mass percent of alumina to a ceramic substrate 12 having a thickness of 0.65 mm. In each sample, the size of the semiconductor integrated circuit 2 disposed on the ceramic substrate 12 was 25.4×25.4 mm, the number of pins was 144 and the diameter of the through holes 14 provided in the alumina substrate 13 was 0.2 mm. FIGS. 8 to 11 show the number of heat cycles and the change in connection resistance between the ceramic substrate 12 and the main substrate 17.

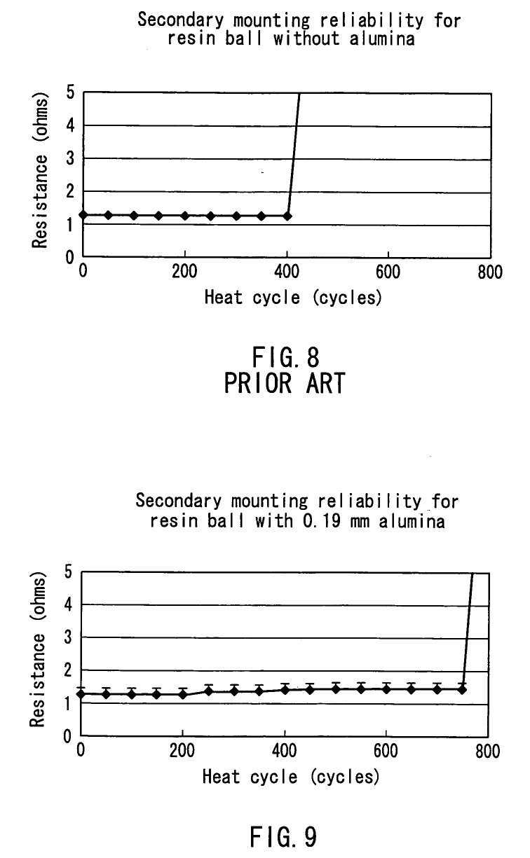

TABLE 2

| | | number of cycles | |
|---|---|---|---|
| | | during which | |
| thickness of | through hole | reliability was | |
| alumina (mm) | filling quality | ensured | remarks |
| nil | — | 400 | FIG. 8 |
| 0.15 | B | — | — |
| 0.19 | A | 750 | FIG. 9 |
| 0.28 | A | 750 | |
| 0.5 | A | 750 | |
| 0.635 | B | — | — |
| 1 | C | — | — |

As described in connection with the results of Table 2, an appropriate thickness of the alumina substrate 13 is 0.19 mm to 0.5 mm, when the diameter of the through holes 14 provided in the alumina substrate 13 is 0.2 mm. The number of heat cycles during which the reliability was ensured was 400 cycles in the case of the sample in which no alumina substrate 13 was bonded (FIG. 8), whereas the number increased to 750 cycles in the case of the samples of the present examples in which the alumina substrate with an appropriate thickness was bonded (FIGS. 9, 10 and 11). That is, the connection made with resin balls according to the present example can attain the reliability about 1.9 times that of the conventional connection.

In the present example, each sample (except for the one in which no alumina substrate was provided) was a substrate formed by bonding an alumina substrate containing 96 mass percent of alumina to a ceramic substrate. In each sample, the thickness of the ceramic substrate was 0.65 mm, the size of the semiconductor integrated circuit 2 was 25.4×25.4 mm, and the number of pins was 144. However, the thickness of the ceramic substrate is not limited to 0.65 mm.

FIG. 2 is a cross-sectional view of a resin ball 29 connecting the circuit board 11 and the main substrate 17 electrically and mechanically. In FIG. 2, the reference numeral 25 denotes a spherical resin core, and 26 denotes a nickel layer covering the outer surface of the resin core. The numeral 27 denotes a copper layer covering the nickel layer 26, and 28 denotes a solder layer covering the copper layer 27. The resin ball 29 as a whole also may be spherical. The resin ball 29 is highly electrically conductive, since it includes the copper layer 27.

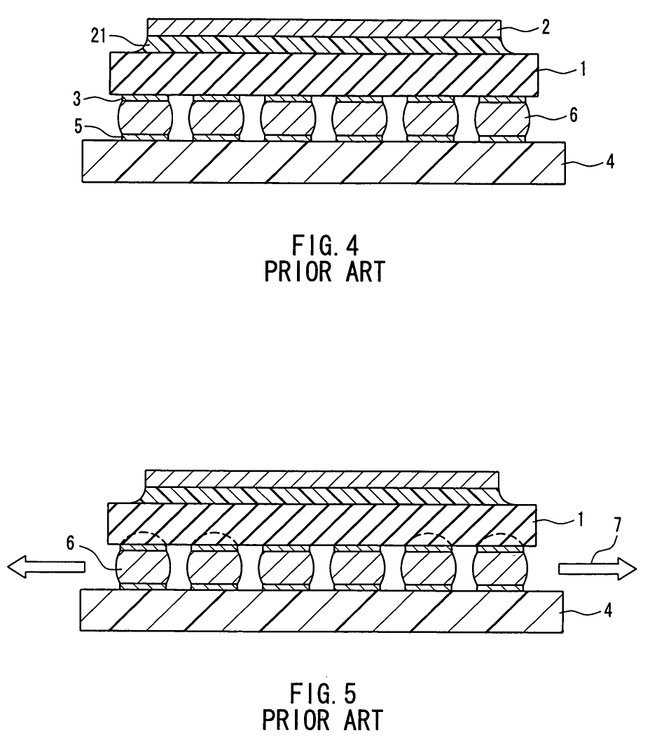

FIG. 3 is a cross-sectional view of the terminal pads 16 of the circuit board 11 and the connection pads 18 of the main substrate 17 that are electrically and mechanically connected with the resin ball 29. With the use of the above-described resin ball 29, the resin core 25 alters its shape in response to a thermal stress and absorbs distortion, so that it is possible to prevent the generation of stress in the circuit board 11 and the main substrate 17 even when they differ in thermal expansion coefficient.

The circuit board according to the present invention prevents cracking due to a stress between two different materials that is caused by the difference in thermal expansion coefficient, by bonding a higher-strength substrate to a lower-strength substrate, and is useful for devices using a ceramic substrate and the like.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

1. A circuit board comprising a plurality of substrates fixed on a main substrate with solder,
wherein the plurality of substrates comprise a substrate having a smaller thermal expansion coefficient than the main substrate, and
wherein the plurality of substrates are made by bonding together a ceramic substrate and a substrate having a higher strength than the ceramic substrate, the higher-strength substrate being bonded to the main substrate side of the ceramic substrate.

2. The circuit board according to claim 1,
wherein the higher-strength substrate is an alumina substrate.

3. The circuit board according to claim 2,
wherein the alumina substrate has a thickness in the range of at least 0.19 mm and at most 0.5 mm.

4. The circuit board according to claim 2,
wherein the alumina substrate is provided with at least one through hole in thickness direction, and a conductive paste is filled into the through hole so as to achieve electrical conduction.

5. The circuit board according to claim 4,
wherein the through hole has a diameter in the range of at least 0.1 mm and at most 0.3 mm.

6. The circuit board according to claim 5,
wherein the following relation ship is satisfied:
0.9B≦A≦2.5B
where A is a diameter of the through hole and B is a thickness of the alumina substrate.

7. The circuit board according to claim 4,
wherein a wiring pattern is provided on the alumina substrate, the wiring pattern is connected to the through hole and a connection is made through the wiring pattern to another circuit disposed on the ceramic substrate.

8. The circuit board according to claim 2,
wherein a terminal pad for connection disposed on the alumina substrate and a connection pad for connection disposed on the main substrate are connected with a resin ball formed by a spherically formed resin, at least one layer of a conductive metal covering an outer surface of the resin and a solder layer covering an outer surface of the metal.

9. The circuit board according to claim 8,
wherein the metal layer of the resin ball is copper.

10. The circuit board according to claim 2,
wherein a terminal pad for connection disposed on the alumina substrate and a connection pad for connection disposed on the main substrate are connected with a solder ball comprising metal.

11. The circuit board according to claim 1,
wherein the ceramic substrate and the higher-strength substrate are integrated in one piece by sintering.
